(19) United States
(12) Patent Application Publication
(10) Pub. No.: US 2025/0167106 A1
(43) Pub. Date: May 22, 2025

(54) INTERCONNECT STRUCTURE INCLUDING METAL LINES HAVING DIFFERENT METAL HEIGHTS

(71) Applicant: SAMSUNG ELECTRONICS CO., LTD.

(72) Inventors: Jaemyung CHOI, Niskayuna, NY (US); Kang-ill SEO, Springfield, VA (US)

(73) Assignee: SAMSUNG ELECTRONICS CO., LTD., (omitted)

(21) Appl. No.: 18/738,802

(22) Filed: Jun. 10, 2024

Related U.S. Application Data
(60) Provisional application No. 63/601,028, filed on Nov. 20, 2023.

(51) Int. Cl. H01L 23/522; H01L 23/528; H01L 23/532

(52) U.S. Cl. CPC H01L 23/5226; H01L 23/528; H01L 23/53257

(57) ABSTRACT

Provided is a semiconductor device which includes: a base layer including at least one transistor structure; and an interconnect structure above the base layer in a 3^{rd} direction, wherein the interconnect structure includes a 1^{st} metal line, a 2^{nd} metal line, and at least one another metal line extended in a 1^{st} direction and arranged at a 2^{nd} direction, wherein at least a 1^{st} portion of the 1^{st} metal line having a 1^{st} metal-to-metal distance to at least a portion of another metal line adjacent thereto in the 2^{nd} direction has a greater height than at least a 1^{st} portion of the 2^{nd} metal line having a 2^{nd} metal-to-metal distance to at least a portion of another metal line adjacent thereto in the 2^{nd} direction, wherein the 1^{st} metal-to-metal distance is greater than the 2^{nd} metal-to-metal distance, and wherein the 1^{st} direction and the 2^{nd} direction horizontally intersect each other, and vertically intersect the 3^{rd} direction.

### CROSS-REFERENCE TO RELATED APPLICATIONS

This application is based on and claims priority from U.S. Provisional Application Nos. 63/601,028 filed on Nov. 20, 2023 in the U.S. Patent and Trademark Office, the disclosure of which is incorporated herein in its entirety by reference.

### BACKGROUND

### 1. Field

Apparatuses and methods consistent with example embodiments of the disclosure relate to a semiconductor device including an interconnect structure in which metal lines having different metal heights are formed.

### 2. Description of the Related Art

Performance of a semiconductor device is affected by how an interconnect structure is formed in the semiconductor device. The interconnect structure of a semiconductor device includes a back-end-of-line (BEOL) structure such as metal lines and vias which connect front-end-of-line (FEOL) structures to a voltage source or other circuit elements directly or through middle-of-line (MOL) structures. The FEOL structures may include a channel structure, source/drain regions, a gate structure forming a transistor of a semiconductor device, and the MOL structures may include contact plugs respectively formed on the source/drain regions and the gate structure of the transistor.

As semiconductor devices are developed to have a high device density and performance, design and formation of an interconnect structure including metal lines and vias becomes more difficult and complicated while improved resistance and capacitance (RC) characteristics are required for the semiconductor device.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

The disclosure provides example embodiments of a semiconductor device including an interconnect structure in which different-height metal lines and/or different-height vias are formed.

According to one or more embodiments, there is provided a semiconductor device which may include: a base layer including at least one transistor structure; and an interconnect structure above the base layer in a 3^{rd} direction, wherein the interconnect structure includes a 1^{st} metal line, a 2^{nd} metal line, and at least one another metal line extended in a 1^{st} direction and arranged at a 2^{nd} direction, wherein at least a 1^{st} portion of the 1^{st} metal line having a 1^{st} metal-to-metal distance to at least a portion of another metal line adjacent thereto in the 2^{nd} direction has a greater height than at least a 1^{st} portion of the 2^{nd} metal line having a 2^{nd} metal-to-metal distance to at least a portion of another metal line adjacent thereto in the 2^{nd} direction, wherein the 1^{st} metal-to-metal distance is greater than the 2^{nd} metal-to-metal distance, and wherein the 1^{st} direction and the 2^{nd} direction horizontally intersect each other, and vertically intersect the 3^{rd}direction.

According to one or more embodiments, there is provided a semiconductor device which may include: a base layer including at least one transistor structure; and an interconnect structure above the base layer in a 3^{rd} direction, wherein the interconnect structure includes a plurality of metal lines extended in a 1^{st} direction and arranged at a 2^{nd} direction, wherein, in the plurality of metal lines, a 1^{st} metal line includes a 1^{st} portion having a 151 metal-to-metal distance to at least a portion of a 2^{nd} metal line and a 2^{nd} portion having a 2^{nd} metal-to-metal distance to at least a portion of a 3^{rd} metal line, wherein a top surface of the 1^{st} portion is at a level higher than a top surface of the 2^{nd} portion, and wherein the 1^{st} direction and the 2^{nd} direction are horizontally intersect each other, and vertically intersect the 3^{rd} direction.

According to one or more embodiments, there is provided a semiconductor device which may include: a base layer including at least one transistor structure; and an interconnect structure above the base layer in a 3^{rd} direction, wherein the interconnect structure includes a 1^{st} top via and a 2^{nd} top via formed on a 1^{st} portion and a 2^{nd} portion of a 1^{st} metal line without a connection surface, boundary or interface therebetween, wherein the 1^{st} top via has a greater height than the 2^{nd} top via, and wherein a horizontal distance between the 1^{st} top via and at least a portion of another metal line adjacent thereto is greater than a horizontal distance between the 2^{nd} top via and at least a portion of another metal line adjacent thereto

According to one or more embodiments, there is provided a semiconductor device which may include: a base layer including a transistor structure; and an interconnect structure above the base layer in a 3^{rd} direction, wherein the interconnect structure includes: a 1^{st} power rail connected to a positive voltage source; a 1^{st} metal line which is a bit line of a static random-access memory (SRAM); and a 2^{nd} metal line which is a word line of the SRAM or a 2^{nd} power rail connected to a negative voltage source, wherein the 1^{st} power rail has a greater metal volume than the 1^{st} metal line, and wherein the 2^{nd} metal line has a greater metal volume than the 1^{st} metal line.

According to one or more embodiments, there is provided a method of manufacturing a semiconductor device. The method may include: 1^{st} patterning a metal structure to form a plurality of metal lines including a 1^{st} metal line and a 2^{nd} metal line extended in a 1^{st} direction and arranged in a 2^{nd} direction, and 2^{nd} patterning the 1^{st} metal line and the 2^{nd} metal line such that at least a 1^{st} portion of a 1^{st} metal line having a 1^{st} metal-to-metal distance to at least a portion of another metal line adjacent thereto in the 2^{nd} direction has a greater height than at least a 1^{st} portion of a 2^{nd} metal line having a 2^{nd} metal-to-metal distance to at least a portion of another metal line adjacent thereto in the 2^{nd} direction, wherein the 1^{st} metal-to-metal distance is greater than the 2^{nd} metal-to-metal distance, and wherein the 1^{st} direction and the 2^{nd} direction are horizontally intersect each other, and vertically intersect the 3^{rd} direction.

According to one or more embodiments, there is provided a method of manufacturing a semiconductor device. The method may include: patterning a metal structure to form a 1^{st} metal line extended in a 1^{st} direction; and patterning the 1^{st} metal line to form a 1^{st} portion and a 2^{nd} portion such that the 1^{st} portion has a greater height than the 2^{nd} portion in a 3rd direction, and a protrusion which has a same height as the 1^{st} portion in the 3^{rd} direction is formed on the 2^{nd} portion, wherein the 1^{st} portion of the 1^{st} metal line has a 1^{st} metal-to-metal distance at least a portion of a 2^{nd} metal line adjacent thereto in a 2^{nd} direction, wherein the 2^{nd} portion of the 1^{st} metal line has a 2^{nd} metal-to-metal distance to at least a portion of still a 3rd metal line adjacent thereto in the 2^{nd} direction, wherein the 1^{st} metal-to-metal distance is greater than the 2^{nd} metal-to-metal distance, and wherein the 1^{st} direction and the 2^{nd} direction are horizontally intersect each other, and vertically intersect the 3^{rd} direction.

### BRIEF DESCRIPTION OF DRAWINGS

Example embodiments of the disclosure will be more clearly understood from the following detailed description taken in conjunction with the accompanying drawings as follows.

FIGS. 1A-1D illustrate an interconnect structure in which metal lines having different heights and vias having different heights are formed, according to one or more embodiments.

FIGS. 2A-2D illustrate an interconnect structure in which metal lines having different metal heights are formed, according to one or more embodiments.

FIGS. 3A and 3B are a flowchart of manufacturing the interconnect structure shown in FIG. 1A-1D, according to one or more embodiments.

FIGS. 4A-4D to 10A-10D illustrate intermediate interconnect structures after respective steps of manufacturing the interconnect structure shown in FIG. 1A-1D, according to one or more embodiments.

FIG. 11 is a flowchart of manufacturing the interconnect structure shown in FIG. 2A-2D, according to one or more embodiments.

FIGS. 12A-12D to 16A-16D illustrate intermediate interconnect structures after respective steps of manufacturing the interconnect structure shown in FIG. 2A-2D, according to one or more embodiments.

FIGS. 17A-17C illustrate a semiconductor cell in which a plurality of metal lines having different heights are placed, according to one or more embodiments.

FIGS. 18A-18C illustrate a semiconductor cell for a static random-access memory (SRAM) in which a plurality of metal lines having different heights are placed, according to one or more embodiments.

FIG. 19 is a schematic block diagram illustrating an electronic device including at least one of the interconnect structures shown in FIGS. 1A-1D and 2A-2D, the interconnect structure based on the semiconductor cell shown in FIGS. 17A-17C, and the interconnect structure based on the semiconductor cell shown in FIGS. 18A-18C, according to one or more embodiments.

### DETAILED DESCRIPTION

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd}” “3^{rd}” “4^{th},” “5^{th}”, “6^{th}” etc. may be used herein to describe various elements, these elements should not be limited by these terms. These terms are only used to distinguish one element from another element. Thus, a 1^{st} element discussed below could be termed a 2^{nd} element without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” or “equal” is used to compare a dimension of two or more elements, the term may cover a “substantially same” or “substantially equal” dimension.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements of a semiconductor device may or may not be described in detail herein or shown in the drawings. For example, MOL or FEOL structures may not be shown or described in detail when these structures are not relevant to the concept of the disclosure. Herein, the term “isolation” may refer to electrical insulation.

Herebelow, various embodiments of the disclosure are described in reference to the accompanying drawings.

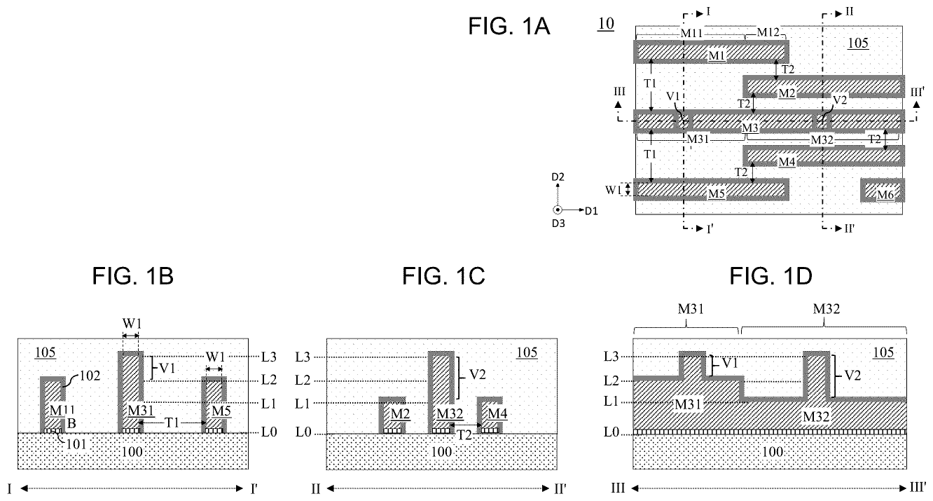

FIGS. 1A-1D illustrate an interconnect structure in which metal lines having different heights and vias having different heights are formed, according to one or more embodiments. FIG. 1A is a plan view of an interconnect structure, and FIGS. 1B-1D are cross-sectional views of the interconnect structure taken along lines I-I′, II-II′ and III-III′ shown in FIG. 1A, respectively.

Referring to FIGS. 1A-1D, an interconnect structure 10 may be formed on a base layer 100 which may be another interconnect structure in a back-end-of-line (BEOL) layer including the interconnect structure 10 or a structure included in a middle-of-line (MOL) layer or a front-end-of-line (FEOL) layer. The base layer 100 may also be referred to as a transistor structure including an FEOL structure, an MOL structure and/or a BEOL structure. Thus, the interconnect structure 10 along with the base layer 100 may form a semiconductor device such as a microprocessor or a memory device, not being limited thereto.

The interconnect structure 10 may include a plurality of metal lines M1-M6 extended in a D1 direction and arranged in a D2 direction which intersects the D1 direction. The interconnect structure 10 may also include top vias V1 and V2 formed on the metal line M3. The metal lines M1-M6 and the top vias V1 and V2 may be surrounded by an inter-metal dielectric (IMD) layer 105 which isolates the metal lines M1-M6 with the top vias V1 and V2 thereon from one another.

The metal lines M1-M6 and the top vias V1 and V2 may be formed of a metal such as ruthenium (Ru) that provides material and chemical characteristics (grain size, chemical resistance, thermal stability, etc.) required for forming fine-pitch metal lines for high-density semiconductor devices, according to an embodiment. The characteristics of Ru may also facilitate formation of a metal line and a top via structure thereon. As alternative to Ru, molybdenum (Mo) may be considered, according to another embodiment. The IMD layer 105 may be formed of a low-k dielectric material such as silicon oxide (e.g., SiO₂), not being limited thereto.

Each of the metal lines M1-M6 may be connected to the base layer 100 through an adhesion layer 101 formed of at least one of titanium (Ti), titanium nitride (TiN), tantalum (Ta), tantalum nitride (TaN), etc. The adhesion layer 101 may contribute to strengthening an overall structure of the interconnect structure 10 and prevent delamination (peeling) therebetween during a manufacturing process and a device operation. The adhesion layer 101 may also allow current flow therethrough. A barrier layer 102 may be formed between the IMD layer 105 and each of the metal lines M1-M6 and the top vias V1-V2. The barrier layer 102 may prevent diffusion of metal atoms of the metal lines M1-M6 and the top vias V1 and V2 into the low-k dielectric material forming the IMD layer 105, thereby maintaining integrity of the IMD layer 105 as isolation structure. For this purpose, the barrier layer 102 may include a material including at least one of silicon nitride (e.g., SiN), Ti, TiN, Ta, TaN, etc., which may be the same or different from the material forming the adhesion layer 101. It is to be understood that, in FIG. 1A, the barrier layer 102 on top surfaces of the metal lines M1-M6 and the top vias V1 and V2 are not shown so that the metal lines M1-M6 are not obscured by the barrier layer 102. However, the barrier layer 102 may not be formed on the metal lines M1-M6 with the top vias V1 and V2 thereon considering that Ru itself has an inherent diffusion barrier properties, unlike other metals such as copper (Cu), aluminum (Al), etc., according to one or more other embodiments.

In the interconnect structure 10, the metal lines M1-M6 may all be included in a same metal layer, e.g., M1 layer, among a plurality of metal layers stacked in a D3 direction which intersects the D1 and D2 directions. Thus, a bottom surface of each of the metal lines M1-M6 may be at a same level to contact a top surface of the adhesion layer 101. Further, the metal lines M1-M6 may all have a same width W1 in the D2 direction.

However, top surfaces of at least the metal lines M1-M6 may be at different levels L1 and L2, and thus, these metal lines may have different metal heights based on a level L0 of a top surface of the base layer 100, thereby to have different metal volumes. Moreover, a single metal line may have different heights. For example, the metal line M1 has an M11 portion and an M12 portion having different metal heights, and the M3 metal line has an M31 portion and an M32 portion having different heights, so that their top surfaces are at different levels.

The metal height difference in the interconnect structure 10 may be determined based on the arrangement of metal lines or the type of metal line, for example, how far at least a portion of a metal line is distant from a portion of another metal line adjacent thereto or whether a metal line is resistance dominant or capacitance dominant.

For example, the M11 portion of the metal line M1, the M31 portion of the metal line M3, and the metal line M5 may each be resistance-dominant metal line, while the M12 portion of the metal line M1, the metal line M2, the M32 portion of the metal line M3, and the metal line M4 may each be capacitance-dominant. This is at least because a metal-to-metal distance T1 between the resistance-dominant portions of metal lines in the D2 direction may be greater than a metal-to-metal distance T2 between the capacitance-dominant portions of metal lines in the same D2 direction. The greater the metal volume or the metal height, the smaller the resistance of the metal line, while the closer the distance between metal lines, the greater the contact capacitance between the metal lines. Exceptionally, the resistant-dominant metal line M5 may be distant from the metal line M4 only by the small metal-to-metal distance T2. However, the metal line M5 may have a greater height than the metal line M4 when the metal line M5 is a resistance-sensitive metal line such as a power rail, not being limited thereto, which needs to have a reduced resistance at the expense of increased capacitance. In this case, an entire portion of the metal line M5 may be a resistance-dominant metal line, unlike each of the metal lines M1 and M3 only a portion of which is resistance-dominant.

Herein, a metal-to-metal distance refers to a distance between two adjacent metal lines in the D2 direction, specifically, between a side surface of a metal line and a side surface of anther metal line facing each other in the D2 direction without any intervening metal line therebetween. Thus, for example, the metal line M3 has the two metal-to-metal distances T1 from the M31 portion and T2 from the M32 portion. The metal-to-metal distance T1 is a distance between a side surface of the M31 portion of the metal line M3 and a side surface of the M11 portion of the metal line M1 facing each other in the D2 direction, and a distance between the other side surface of the M31 portion of the metal line M3 and a side surface of the metal line M5 facing each other in the D2 direction. The metal-to-metal distance T2 is a distance between a side surface of the M32 portion of the metal line M3 and a side surface of the metal line M2 facing each other in the D2 direction, and a distance between the other side surface of the M32 portion of the metal line M3 and a side surface of the metal line M4 facing each other in the D2 direction

Thus, considering the metal-to-metal distances between metal lines related to resistance-dominancy and capacitance-dominancy, the M11 portion of the metal line M1, the M31 portion of the metal line M3, and the metal line M5 may each have the top surface at the level L2, higher than the level L1, to have a greater metal volume while they have the same width W1. In contrast, the M12 portion of the metal line M1, the metal line M2, the M32 portion of the metal line M3, and the metal line M4 may each have the top surface at the level L1, lower than the level L2, to have a smaller metal volume while they have the same width W1. In this manner, contact resistance can be reduced at least at the resistance-dominant portions of the metal lines including the M11 portion of the metal line M1 and the M31 portion of the metal line M3, while contact capacitance can be reduced at least at the capacitance-dominant portions of the metal lines including the M12 portion of the metal line M1, the metal line M2 in its entirety, the M32 portion of the metal line M3, and the metal line M4 in its entirely, thereby improving connection performance of a semiconductor device which includes the interconnect structure 10.

As the metal heights are different at the M31 portion and the M32 portion of the single metal line M3, the top vias V1 and V2 respectively formed thereon have different heights to be connected to an upper layer at a same level L3. For example, the top via V2 may have a greater height than the top via V1, and thus, a bottom of the top via V2 is at the level L1 lower than the level L2 of a bottom of the top via V1.

In the meantime, top vias such as the top vias V1 and V2 are introduced to reduce contact resistance and capacitance existing between a metal line and a via formed thereon through a damascene process, which adversely affects at least connection performance of a semiconductor device including the metal line and the via. To form a top via, a metal structure (e.g., Ru) may be first patterned, and recessed except a masked region for via formation through, for example, photolithography/making/etching operations. As a result, the recessed region of the metal structure forms an underlying metal line and the masked region forms a via, i.e., a top via. Thus, the top via and the underlying metal line may be a single continuum structure that does not have a connection surface, a boundary, or an interface therebetween, unlike a damascene via and a damascene metal line which is formed through respective single damascene processes. After the metal line and the top via are patterned, an IMD layer may be formed to enclose the metal line and the top via. Thus, a risk of metal atom diffusion into the IMD layer that occurs in a damascene process may be avoided or reduced in the top via process, so that a barrier layer such as the barrier layer 102 formed in the interconnect structure 10 may not be always needed between the IMD layer and the metal line with the top via thereon or a metal line formed in the top via process. Accordingly, the M3 metal line and each of the top vias V1 and V2 formed in this manner may not have a connection surface, boundary or interface therebetween, and also, the barrier layer 102 may not be necessarily formed in the interconnect structure 10 as shown in FIGS. 1A-ID.

The above embodiments provide the interconnect structure 10 having the different-height metal lines M1-M5 as well as different-height top vias V1-V2. However, an interconnect structure may be formed to provide only different-height metal lines as described below.

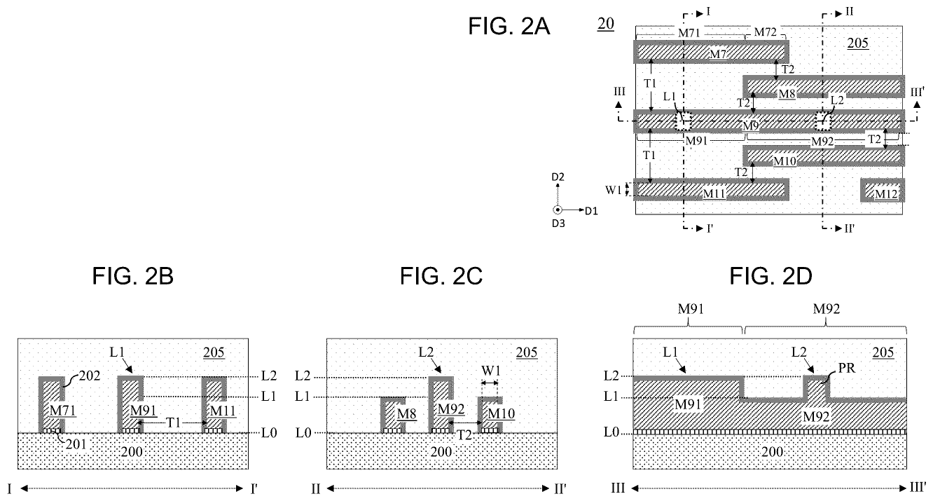

FIGS. 2A-2C illustrate an interconnect structure in which metal lines having different metal heights are formed, according to one or more embodiments. FIG. 2A is a plan view of an interconnect structure, and FIGS. 2B-2D are cross-sectional views of the interconnect structure taken along lines I-I′, II-II′ and III-III′ shown in FIG. 2A, respectively.

Referring to FIGS. 2A-2C, an interconnect structure 20, like the interconnect structure 10, may also be formed on a base layer 200 which may be another interconnect structure in a BEOL layer including the interconnect structure 20 or a structure in an MOL layer or an FEOL layer. The base layer 200 may also be referred to as a transistor structure including an FEOL structure, an MOL structure and/or a BEOL structure. Thus, the interconnect structure 20 along with the base layer 200 may form a semiconductor device such as a microprocessor or a memory device.

The interconnect structure 20 may also include a plurality of metal lines M7-M12 extended in the D1 direction, arranged in the D2 direction, and surrounded by an IMD layer 105 which isolates the metal lines M7-M12 from one another. The metal lines M7-M12 and the TIMD layer 105 may correspond to the metal lines M1-M6 and the IMD layer 105 of the interconnect structure 10, respectively. The metal lines M7-M12 and the IMD layer 205 may be formed of the same materials as the metal lines M1-M6 and the IMD layer 105, respectively. The interconnect structure 20 may also include an adhesion layer 201 and a barrier layer 202 which are the same as or similar to the adhesion layer 101 and the barrier layer 102 in the interconnect structure 10.

In addition, as in the interconnect structure 10, all of the metal lines M7-M12 in the interconnect structure 20 may be included in a same metal layer, e.g., M1 layer, among a plurality of metal layers stacked in the D3 direction. Thus, a bottom surface of each of the metal lines M7-M12 may be at a same level to contact a top surface of the adhesion layer 201. Further, the metal lines M1-M6 may all have a same width W1 in the D2 direction.

Further, top surfaces of at least the metal lines M7-M12 may be at different levels L1 and L2, so that these metal lines may have different metal heights from a level L0 of a top surface of the base layer 200, thereby to have different metal volumes. Moreover, a single metal line may have different heights. For example, the metal line M7 may have an M71 portion and an M72 portion having different heights, and the M9 metal line may have an M91 portion and an M92 portion having different heights.

As in the interconnect structure 10, the metal lines M7-M12 of the interconnect structure 20 may have this metal height difference based on the resistance dominancy and the capacitance dominancy considering metal-to-metal distances T1 and T2 between adjacent portions of metal lines or adjacent metal lines.

For example, the M71 portion of the metal line M7, the M91 portion of the metal line M9, and the metal line M11 arranged in the D2 direction with the metal-to-metal distance T1 and having their top surfaces at the level L2 may be resistance-dominant. In contrast, the M72 portion of the metal line M7, the metal line M8, the M92 portion of the metal line M9, and the metal line M10 also arranged in the D2 direction with the metal-to-metal distance T2, smaller than T1, and having their top surfaces at the level L1, lower than the level L2, may be capacitance-dominant. Thus, contact resistance can be reduced at least at the resistance-dominant portions of the metal lines while contact capacitance can be reduced at least at the capacitance-dominant portions of the metal lines, thereby improving connection performance of a semiconductor device including the interconnect structure 20

However, while the interconnect structure 10 may include the top vias V1 and V2 on the metal lines M31 and M32, respectively, the interconnect structure 20 may not include corresponding top vias on the corresponding metal lines M91 and M92, respectively. For example, no top via is formed on the metal line M91 and only a metal protrusion PR is formed on the metal line M92. This interconnect structure 20 is in a form prior to be connected to an upper-layer interconnect structure including a plurality of vias landing on any of the metal lines M7-M12 including the metal lines M91 and M92.

For example, vias of an upper layer may be formed to land on top surfaces of the M91 portion and the M92 portion of the metal line M9 which respectively provide via landing regions A1 and A2 shown in FIGS. 2A-2D. Here, the via landing region A2 of the M92 portion of the metal line M9 may be provided on a top surface of the metal protrusion PR. This metal protrusion PR is formed on the M92 portion to provide the via landing region A2 so that the vias landing on the metal lines M7-M12 can have their bottoms or bottom surfaces at the same level L2. These vias of the upper-layer interconnect structure to land on the metal lines M7-M12 may be any type of via such as a top via or a damascene via formed though a damascene process, while the vias V1 and V2 formed on the metal line M3 in the interconnect structure 10 shown in FIGS. 1A-1D are all top vias.

For the foregoing purpose, the metal line M9 may be formed such that even if the M92 portion thereof is capacitance dominant, the metal protrusion PR is formed to have the top surface at the same level as the top surface of the M91 portion or the other resistance-dominant metal lines to provide the via landing region A2.

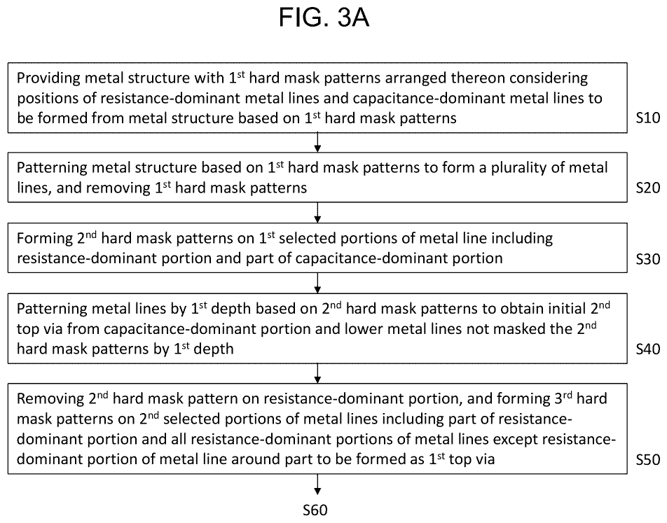

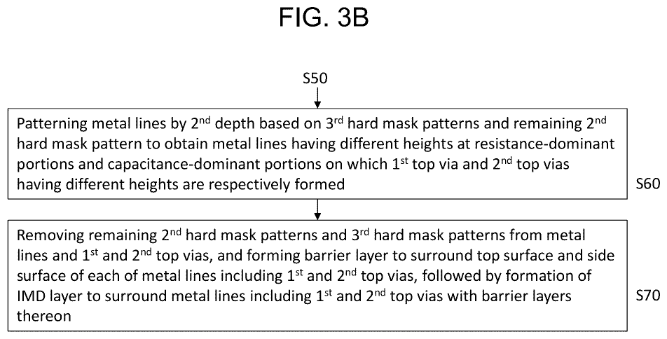

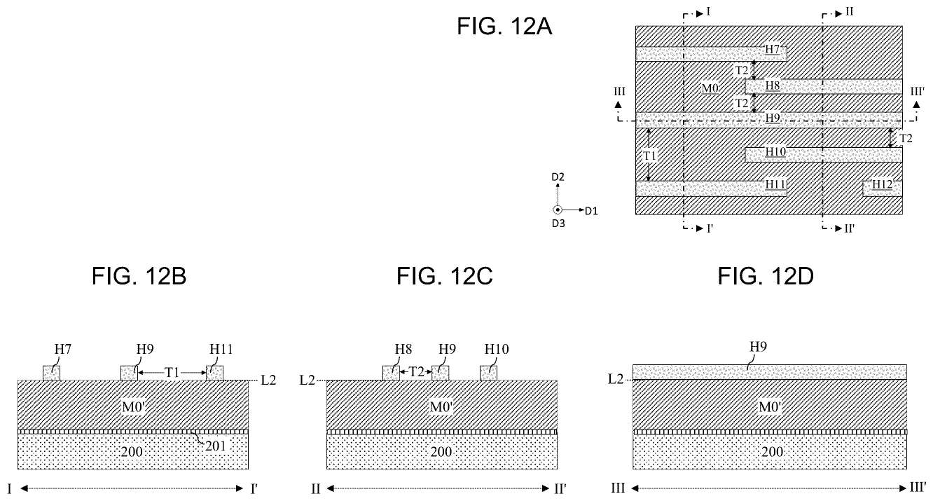

Herebelow, a methods of manufacturing the interconnect structure 10 is provided in reference to FIGS. 3 through FIGS. 10A-10D, and a method of manufacturing the interconnect structure 20 is provided in reference to FIGS. 12 through FIGS. 17A-17C.

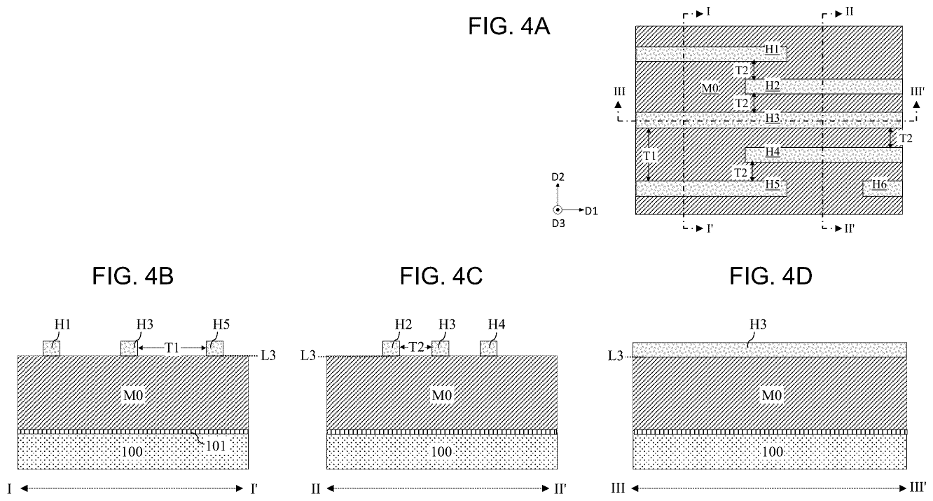

FIGS. 3A and 3B are a flowchart of manufacturing the interconnect structure 10, according to one or more embodiments, and FIGS. 4A-4D to 10A-10D illustrate intermediate interconnect structures after respective steps of manufacturing the interconnect structure 10, according to one or more embodiments. It is to be understood that the same reference characters or numerals shown in FIGS. 1A-1D may be used to refer to the same structural elements described herebelow.

In step S10, a metal structure may be provided with a plurality of 1^{st} hard mask patterns thereon at positions where a plurality of metal lines are to be formed therebelow, wherein the 1^{st} hard mask patterns are arranged on the metal structure considering positions of resistance-dominant portions of metal lines and capacitance-dominant portions of metal lines to be formed based on the 1^{st} hard mask patterns.

Referring to FIGS. 4A-4D, a metal structure M0 may be formed on a base layer 100 with an adhesion layer 101 therebetween prior to a process of forming an interconnect structure including a plurality of metal lines and top vias from the metal structure M0. However, the disclosure is not limited thereto. An interconnect structure may be first manufactured from the metal structure M0, and then, attached to or combined with the base layer 100 with the adhesion layer 101 therebetween, according to one or more other embodiments.

The metal structure M0 may be planarized at its top through, for example, chemical-mechanical polishing (CMP) to have a plain top surface at a level L3. The metal structure M0 may be formed of a material such as ruthenium (Ru) to facilitate formation of a metal line and formation of a top via directly from that metal line in later steps.

A plurality of 1^{st} hard mask patterns H1-H6 may be formed on a top surface of the metal structure M0 at positions where a plurality of metal lines and top vias are to be patterned therebelow in a next step. Since the shapes and forms of the 1^{st} hard mask patterns H1-H6 are to be transferred to the metal lines to be formed therebelow through masking and etching operations in a next step, the 1^{st} hard mask patterns H1-H6 may be formed on the metal structure M0 considering where each of the metal lines is to be arranged in an interconnect structure to be formed from the metal structure M0.

For example, the 1^{st} hard mask pattern H1-H6 extended in the D1 direction may be arranged in the D2 direction such that the 1^{st} hard mask patterns H1, H3 and H5 for resistance-dominant portions of the metal lines are arranged with a pattern-to-pattern distance T1 in the D2 direction. Further, the 1^{st} hard mask patterns H1-H4 for capacitance-dominant metal lines among the metal lines and capacitance-dominant portions of the metal lines are arranged with a pattern-to-pattern distance T2 which is smaller than T1. Although the 1^{st} hard mask pattern H5 is for a resistance-dominant metal line in its entirety, the 1^{st} hard mask pattern H5 may be distant from the adjacent 1^{st} hard mask pattern H4 by the pattern-to-pattern distance T2. This is because the metal line to be patterned based on the 1^{st} hard mask pattern H5 is resistance-sensitive regardless of its distance to the adjacent metal line H4, as will be described later.

The formation of the 1^{st} hard mask patterns H1-H6 may be performed through, for example, photolithography and etching. The 1^{st} hard mask patterns H1-H6 may include a material such as silicon nitride (e.g., SiN), titanium nitride (TiN), silicon oxynitride (SiON), etc.

In step 520, the metal structure provided in the previous step may be patterned based on the 1^{st} hard mask patterns to form a plurality of metal lines, and the 1^{st} hard mask patterns may be removed.

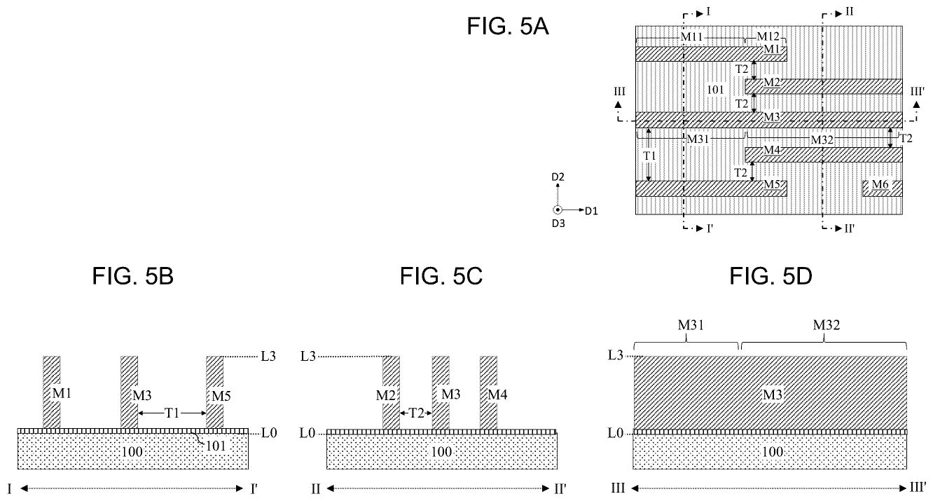

Referring to FIGS. 5A-5D, the metal structure M0 may be patterned based on the 1^{st} hard mask patterns H1-H6 through, for example, dry etching or wet etching, not being limited thereto, to form a plurality of metal lines M1-M6 corresponding to the 1^{st} hard mask patterns H1-H6. Then, the 1^{st} hard mask patterns H1-H6 may be removed to expose the metal lines M1-M6 through, for example, stripping or ashing, not being limited thereto.

For example, an M11 portion of the metal line M1, an M31 portion of the metal line M3, and the metal line M5 may be formed to have a metal-to-metal distance T1 (equal to the pattern-to-pattern distance T1) in the D2 direction. Further, an M12 portion of the metal line M1, the metal line M2, an M32 portion of the metal line M3, and the metal line M4 may be formed to have a metal-to-metal distance T2 (equal to the pattern-to-pattern distance T2), which is smaller than T1. As described in the previous step, the metal line M5 and the adjacent metal line M4 may be formed to have the metal-to-metal distance T2. Here, the M11 portion of the metal line M1 and the M31 portion of the metal line M3 are to be formed as resistance-dominant portions of the metal lines M1 and M3, respectively, in a later step. In contrast, the metal lines M2 and M4 are to be formed as capacitance-dominant metal lines in their entireties, and the metal line M5 is to be formed as a resistance-dominant metal line in its entirety, in a later step.

As the 1^{st} hard mask patterns H1-H6 are formed on the plane top surface of the metal structure M0, the metal lines M1-M6 patterned based on the 1^{st} hard mask patterns H1-H6 may also have a same height from a level L0 of a top surface of the base layer 100 so that top surfaces thereof are at the same level L3.

In step S30, 2^{nd} hard mask patterns may be formed on 1^{st} selected portions of a metal line, among the metal lines, where top vias are to be formed therebelow, wherein the 1^{st} selected portions include a resistance-dominant portion of the metal line including a part where a 1^{st} top via is to be formed, and a part of a capacitance-dominant portion of the metal line which is to be formed as a 2^{nd} top via.

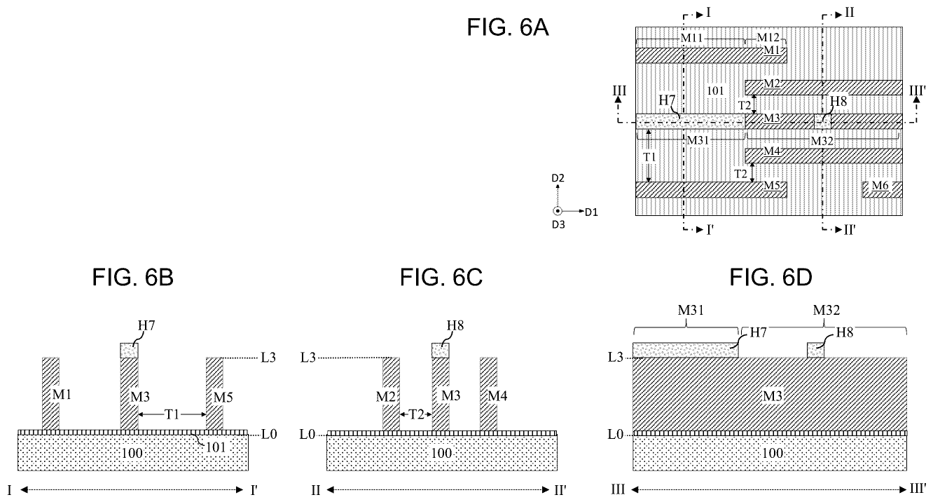

Referring to FIGS. 6A-6D, 2^{nd} hard mask patterns H7 and H8 may be respectively formed on the metal line M3 at the M31 portion including a part where a 1^{st} top via V1 is formed in a later step and a part of the M32 portion of the metal line M3 which is to be formed as a 2^{nd} top via V2 in a later step.

The formation of the 2^{nd} hard mask patterns H7 and H8 may be performed through, for example, photolithography and etching. The 2^{nd} hard mask patterns H7 and H8 may also include a material such as silicon nitride (e.g., SiN), TiN, SiON, etc.

At this time, an IMD layer may be formed to surround the metal lines M1-M6 to facilitate formation of the 2^{nd} hard mask patterns H7 and H8 and a subsequent patterning operation based on the 2^{nd} hard mask patterns H7 and H8 in a next step. The IMD layer, if any, may be formed of depositing a low-k dielectric material such as silicon oxide (e.g., SiO₂), not being limited thereto through, for example, at least one of physical vapor deposition (PVD), chemical vapor deposition (CVD), plasma enhanced chemical vapor deposition (PECVD), atomic layer deposition (ALD), etc., followed by planarization such as CMP, not being limited thereto.

In step 540, the metal lines may be patterned by a predetermined 1^{st} depth based on the 2^{nd} hard mask patterns to obtain an initial 2^{nd} top via from a capacitance-dominant portion of the metal line, wherein the metal lines not masked by the 2^{nd} hard mask patterns may be lowered by the 1^{st} depth.

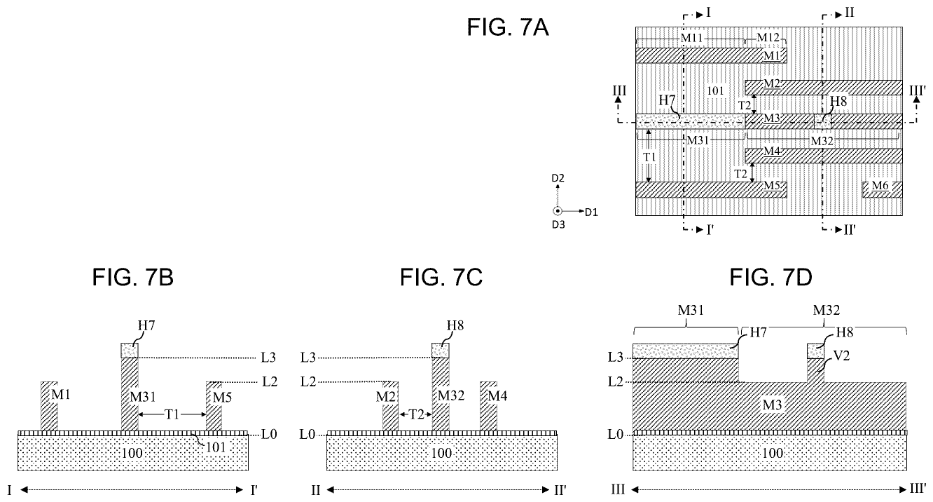

Referring to FIGS. 7A-7D, the metal lines M1-M6 may be patterned by a predetermined 1^{st} depth based on the 2^{nd} hard mask patterns H7 and H8. Thus, the part of the M32 portion (capacitance-dominant) of the metal line M3 masked by the 2^{nd} hard mask pattern H8 may be formed as an initial 2^{nd} top via V2. Further, the metal lines M1-M6 except the M31 portion of the metal line M3 masked by the 2^{nd} hard mask patterns H7 may be patterned by the 1^{st} depth so that top surfaces thereof are at a level L2 which is lower than top surfaces of the initial 2^{nd} top via at the level L3. At this time, the M32 portion of the metal line M3 masked by the 2^{nd} hard mask pattern H7 can have its top surface at the level L3.

The patterning operation in this step may also be performed through, for example, dry etching or wet etching, not being limited thereto.

In step S50, a 2^{nd} hard mask pattern, among the 2^{nd} hard mask patterns, formed on the resistance-dominant portion of the metal line where the 1^{st} top via is to be formed may be removed, and 3^{rd} hard mask patterns may be formed on 2^{nd} selected portions of the metal lines patterned in the previous step, wherein the 2^{nd} selected portions include a part of the resistance-dominant portion of the metal line which is to be formed as the 1^{st} top via and all resistance-dominant portions of the metal lines except the resistance-dominant portion of the metal line around the part which is to be formed as the 1^{st} top via.

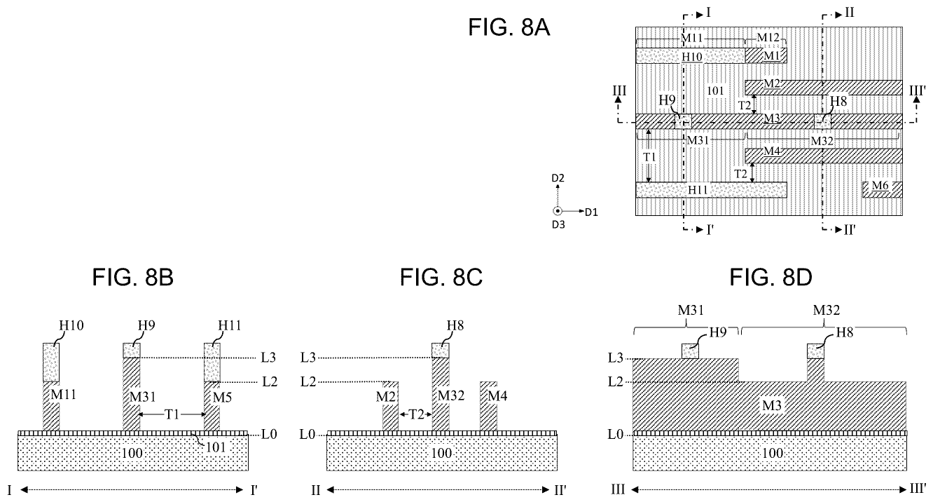

Referring to FIGS. 8A-8D, the 2^{nd} hard mask pattern H7 on the metal line M3 at the M31 portion of the metal lime M3 may be removed through, for example, stripping or ashing while the 2^{nd} hard mask pattern H8 may remain on the initial 2^{nd} top via V2 on the M32 portion of the M3 metal line. Then, a 3^{rd} hard mask pattern H9 may be formed on a part of the M31 portion of the metal line M3 which is to be formed as the 1^{st} top via.

Further, other 3^{rd} hard mask patterns H10 and H11 may be formed on the M11 portion of the metal line M1 and an entirety of the metal line M5, respectively. The M11 portion of the M1 metal line masked by the 3^{rd} hard mask pattern H10 is to be formed as a resistance-dominant portion of the M1 metal line while the M12 portion which is not masked by the 3^{rd} hard mask pattern H10 is to be formed as a capacitance-dominant portion of the M1 metal line. The metal line M5 masked by the 3^{rd} hard mask pattern H11 may be formed as a resistance-dominant metal line in its entirety even if this metal line is distant from the adjacent metal line M4 by the small distance T2 in the D2 direction. This is because the metal line M5 may be very sensitive to resistance. For example, the metal line M5 may be a power rail which needs to have a reduced resistance by having a greater volume or height at the expense of increased capacitance.

In the meantime, the metal lines M2 and M4 which are to be formed as capacitance-dominant metal lines may also not be masked by the 3^{rd} hard mask patterns H10 and H11 or any other hard mask patterns so that another patterning can be performed in a next step on these metal lines along with the metal line M6, the M12 portion of the metal line M1, and the M31 portion of the metal line M31 except the part to be formed as the 1^{st} top via V1.

In step S60, the metal lines may be patterned by a predetermined 2^{nd} depth based on the 3^{rd} hard mask patterns and the remaining 2^{nd} hard mask pattern to obtain the metal lines having different heights at resistance-dominant portions and capacitance-dominant portions on which the 1^{st} top via and a 2^{nd} top vias are formed to have different heights thereon, respectively.

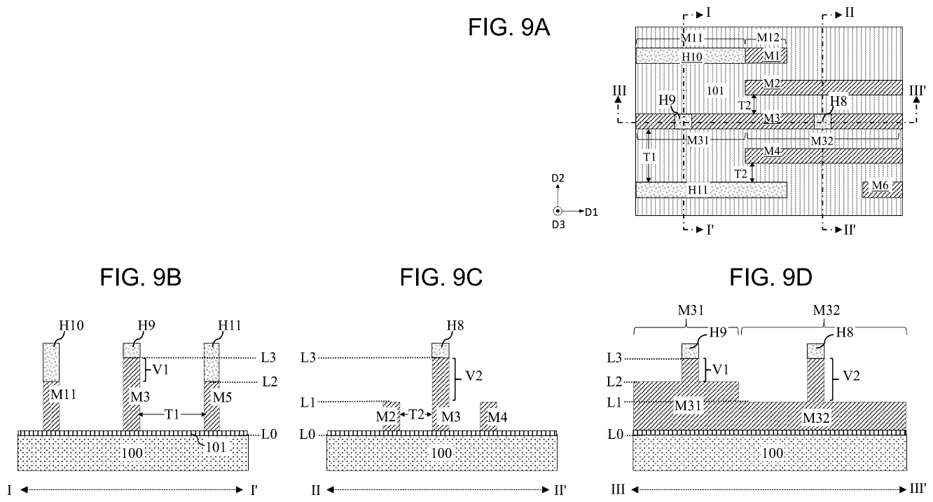

Referring to FIG. 9A-9C, the metal lines M1-M6 including the initial 2^{nd} top via V2 at portions which are not masked by the 2^{nd} hard mask pattern H8 and the 3^{rd} hard mask patterns H9-H11 may be patterned by a predetermined 2^{nd} depth.

By this patterning, the metal line M1 at the M11 portion, the metal line M3 at the M31 portion, and the metal line M5 in its entirety may be formed as resistance-dominant metal lines with their top surfaces at the level L2. Further, by this patterning, the metal line M1 at the M12 portion, the metal lines M2, M4 and M6 in their entireties, and the metal line M3 at the M32 portion may be formed as capacitance-dominant metal lines with their top surfaces at the level L1 lower than the level L2.

Moreover, the part of the M31 portion of the metal line M3 masked by the 3^{rd} hard mask pattern H9 may be formed as the 1^{st} top via V1, and the 2^{nd} top via still masked by the 2^{nd} hard mask pattern H8 may be formed as a 2^{nd} top via having a greater height than the initial 2^{nd} top via by a difference between the levels L2 and L3.

Further, although the 1^{st} and 2^{nd} top vias both may have their top surfaces at the level L3 higher than the level L2, the top via V2 may have a greater height than the 1^{st} top via V1 because the 2^{nd} top via V2 may have its bottom at the level L1 while the 1^{st} top via V1 has its bottom at the level L2 higher than the level L1.

In step 570, the remaining 2^{nd} hard mask patterns and the 3^{rd} hard mask patterns may be removed from the metal lines and the 1^{st} and 2^{nd} top vias, and a barrier layer may be formed to surround a top surface and a side surface of each of the metal lines including the 1^{st} and 2^{nd} top vias, followed by formation of an IMD layer to surround the metal lines including the 1^{st} and 2^{nd} top vias with the barrier layers thereon.

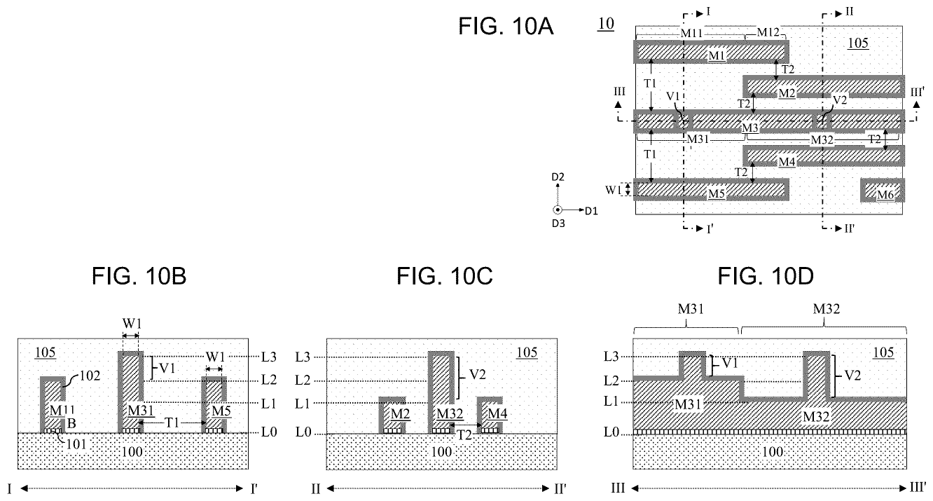

Referring to FIGS. 10A-10D, the 2^{nd} hard mask pattern H8 and the 3^{rd} hard mask patterns H9-H11 may be removed from the top vias V1 and V2, the M11 portion of the metal line M1, and the metal line M5 through, for example, stripping or ashing, to expose top surfaces thereof. Then, a barrier layer 102 may be formed on the exposed top surfaces and side surfaces of the metal lines M1-M6 with the top vias V1 and V2 thereon through, for example, atomic layer deposition (ALD) of at least one of silicon nitride (e.g., SiN), Ti, TiN, Ta, TaN, etc.

Further, an IMD layer 105 may be formed to surround the metal lines M1-M6 with the top vias V1 and V2 thereon surrounded by the barrier layer 102 by depositing a low-k dielectric material such as silicon oxide (e.g., SiO₂), not being limited thereto through, for example, PVD, CVD, PECVD, ALD, or so on followed by CMP, not being limited thereto.

Through the above-described steps, an interconnect structure 10 shown in FIGS. 1A-1D may be manufactured to include the metal lines M1-M6 with the top vias V1 and V2 thereon, in which the resistance-dominant portions have a greater height and the capacitance-dominant portions have smaller height to achieve improved RC characteristics.

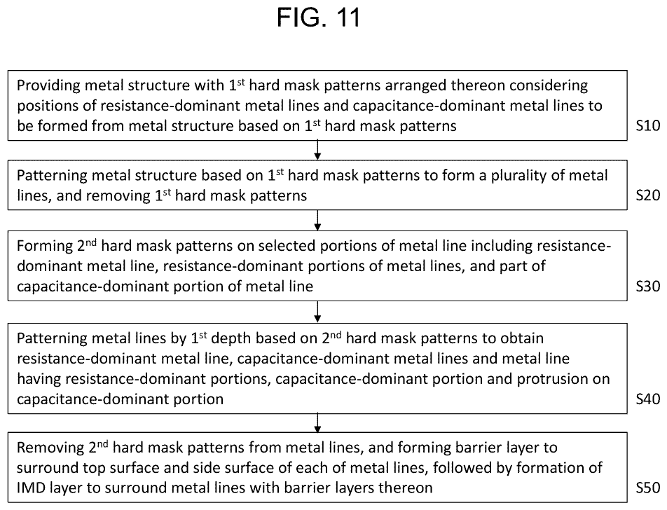

Now, a method of manufacturing the interconnect structure 20 shown in FIGS. 2A-2D is provided herebelow in reference to FIG. 11 through FIGS. 16A-16D.

FIG. 11 is a flowchart of manufacturing the interconnect structure 20, according to one or more embodiments, and FIGS. 12A-12D to 16A-16D illustrate intermediate interconnect structures after respective steps of manufacturing the interconnect structure 20, according to one or more embodiments. It is to be understood that the same reference characters or numerals shown in FIGS. 2A-2D may be used to refer to the same structural elements described herebelow.

In step S10, a metal structure may be provided with a plurality of 1^{st} hard mask patterns thereon at positions where a plurality of metal lines are to be formed therebelow, wherein the 1^{st} hard mask patterns are arranged on the metal structure considering positions of resistance-dominant portions of metal lines and capacitance-dominant portions of metal lines to be formed based on the 1^{st} hard mask patterns.

Referring to FIGS. 12A-12D, a metal structure M0′ may be formed on a base layer 200 with an adhesion layer 201 therebetween prior to a process of forming an interconnect structure including a plurality of metal lines and top vias from the metal structure M0′. However, the disclosure is not limited thereto. An interconnect structure may be first manufactured from the metal structure M0′, and then, attached to or combined with the base layer 200 with the adhesion layer 201 therebetween, according to one or more other embodiments.

The metal structure M0′ may be planarized at its top through, for example, CMP to have a plain top surface at a level L2. The metal structure M0′ may be formed of a material such as ruthenium (Ru) to facilitate formation of a metal line and formation of a top via directly from that metal line in later steps.

A plurality of 1^{st} hard mask patterns H7-H12 may be formed on a top surface of the metal structure M0′, which may be plane, at positions where a plurality of metal lines are to be patterned therebelow in a next step. Since the shapes and forms of the 1^{st} hard mask patterns H7-H12 are to be transferred to the metal lines to be formed therebelow through masking and etching operations in a next step, the 1^{st} hard mask patterns H7-H12 may be formed on the metal structure M0 considering where each of the metal lines is to be arranged in an interconnect structure to be formed from the metal structure M0′.

For example, the 1^{st} hard mask pattern H7-H12 extended in the D1 direction may be arranged in the D2 direction such that the 1^{st} hard mask patterns H7, H9 and H11 for resistance-dominant portions of the metal lines are arranged with a pattern-to-pattern distance T1 in the D2 direction. Further, the 1^{st} hard mask patterns H7-H10 for capacitance-dominant metal lines among the metal lines and capacitance-dominant portions of the metal lines are arranged with a pattern-to-pattern distance T2 which is smaller than T1. Although the 1^{st} hard mask pattern H11 is for a resistance-dominant metal line in its entirety, the 1^{st} hard mask pattern H11 may be distant from the adjacent 1^{st} hard mask pattern H10 by the pattern-to-pattern distance T2. This is because the metal line to be patterned based on the 1^{st} hard mask pattern H11 is resistance-sensitive regardless of its distance to the adjacent metal line H10, as will be described later.

The formation of the 1^{st} hard mask patterns H7-H12 may be performed through, for example, photolithography and etching. The 1^{st} hard mask patterns H7-H12 may include a material such as silicon nitride (e.g., SiN), TiN, SiON, etc.

In step 520, the metal structure provided in the previous step may be patterned based on the 1^{st} hard mask patterns to form a plurality of metal lines, and the 1^{st} hard mask patterns may be removed.

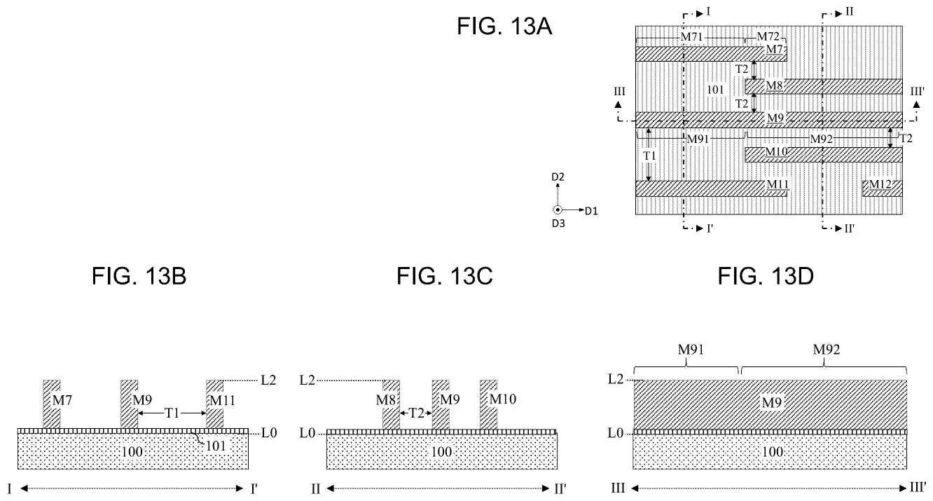

Referring to FIGS. 13A-13D, the metal structure M0′ may be patterned based on the 1^{st} hard mask patterns H7-H12 through, for example, dry etching or wet etching, not being limited thereto, to form a plurality of metal lines M7-M12 corresponding to the 1^{st} hard mask patterns H7-H12. Then, the 1^{st} hard mask patterns H7-H12 may be removed to expose the metal lines M7-M12, for example, stripping or ashing, not being limited thereto

For example, an M71 portion of the metal line M7, an M91 portion of the metal line M9, and the metal line M11 may be formed to have a metal-to-metal distance T1 (equal to the pattern-to-pattern distance T1) in the D2 direction. Further, an M72 portion of the metal line M7, the metal line M8, an M92 portion of the metal line M9, the metal line M10, may be formed to have a metal-to-metal distance T2 (equal to the pattern-to-pattern distance T2), which is smaller than T1. As described in the previous step, the metal line M11 and the adjacent metal line M10 may be formed to have the metal-to-metal distance T2. Here, the M11 portion of the metal line M1 and the M31 portion of the metal line M3 are to be formed as resistance-dominant portions of the metal lines M1 and M3, respectively, in a later step. In contrast, the metal lines M8 and M10 are to be formed as capacitance-dominant metal lines in their entireties, and the metal line M11 is to be formed as a resistance-dominant metal line in its entirety, in a later step.

As the 1^{st} hard mask patterns H7-H12 are formed on the plane top surface of the metal structure M0, the metal lines M7-M12 patterned based on the 1^{st} hard mask patterns H7-H12 may also have a same height from a level L0 of a top surface of the base layer 200 so that top surfaces thereof are at the same level L2.

In step S30, 2^{nd} hard mask patterns may be formed on selected portions of the metal lines including a resistance-dominant metal line, resistance-dominant portions of the metal lines, and a part of a capacitance-dominant portion of a metal line, among the metal lines, on which a via may land in a later step.

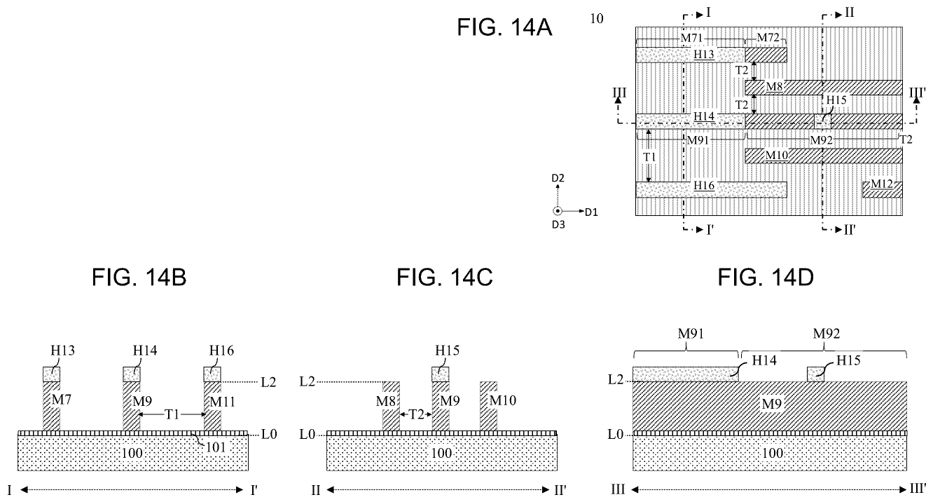

Referring to FIGS. 14A-14D, 2^{nd} hard mask patterns H13-H16 may be respectively formed on selected portions of the metal lines H7-H12. For example, the 2^{nd} hard mask patterns H13 and H14 may be formed on the M71 portion (resistance-dominant) of the metal line M7 and the M91 portion (resistance-dominant) of the metal line M9, respectively, and the 2^{nd} hard mask pattern H15 may be formed on a part of the M92 portion (capacitance-dominant) of the metal line M9 on which a via may land. Further, the 2^{nd} hard mask pattern H16 may be formed on the metal line M11 to be formed as a resistance-dominant metal line in its entirety.

The formation of the 2^{nd} hard mask patterns H13-H16 may be performed through, for example, photolithography and etching. The 2^{nd} hard mask patterns H13-H16 may also include a material such as silicon nitride (e.g., SiN), TiN, SiON, etc.

At this time, an IMD layer may be formed to surround the metal lines M7-M12 to facilitate formation of the 2^{nd} hard mask patterns H13-H16 and a subsequent patterning operation based on the 2^{nd} hard mask patterns H13-H16 in a next step. The IMD layer, if any, may be formed of depositing a low-k dielectric material such as silicon oxide (e.g., SiO₂), not being limited thereto through, for example, at least one of PVD, CVD, PECVD, ALD, etc., followed by planarization such as CMP, not being limited thereto.

In step 540, the metal lines may be patterned by a predetermined 1^{st} depth based on the 2^{nd} hard mask patterns to obtain a resistance-dominant metal line, capacitance-dominant metal lines, and a metal line having a resistance-dominant portion, a capacitance-dominant portion and a protrusion on the capacitance-dominant portion where a via may land in a later step.

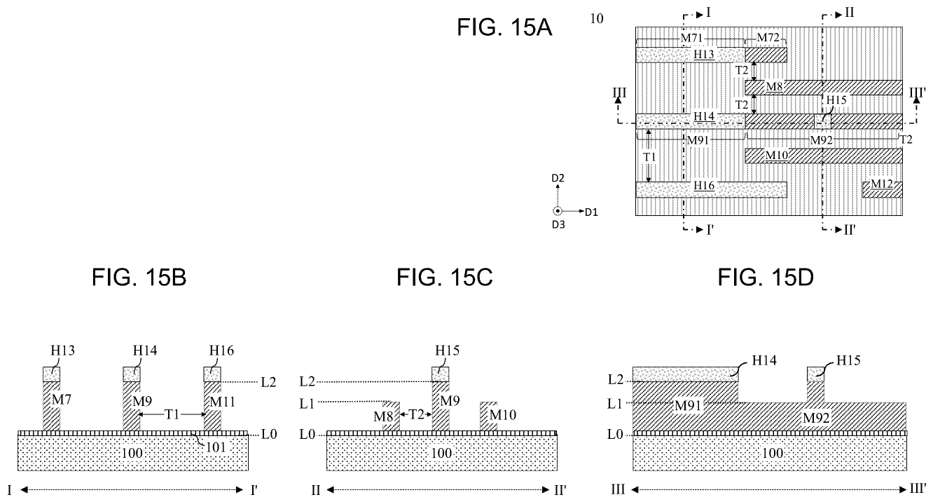

Referring to FIGS. 15A-15D, the metal lines M7-M12 may be patterned by a predetermined 1^{st} depth based on the 2^{nd} hard mask patterns H13-H16. Thus, by this patterning, capacitance-dominant portions of the metal lines M7-M12 which are not masked by the 2^{nd} hard mask patterns H13-H16 may have their top surfaces at a level L1 which is lowered from the level L2 by the 1^{st} depth. These capacitance-dominant portions of the metal lines M7-M12 may include the M72 portion of the metal line M7, the metal lines M8, M10 and M12 in their entireties, and the M92 portion of the metal line M9 except the part masked by the 2^{nd} hard mask pattern H15 and provided for via landing.

Further, by this patterning, the M71 portion of the metal line M7, the M91 portion of the metal line M9, and the metal line M11 in its entirety, which are the resistance-dominant portions, may maintain their top surfaces at the level L2 due to the respective masking by the 2^{nd} hard mask patterns H13, H14 and H16.

Moreover, by this patterning, the part of the M92 portion (capacitance-dominant) of the metal line M9 provided for via landing may be formed as a protrusion PR protruded from the M92 portion so that a top surface thereof is also at the level L2 while the M92 portion is a capacitance-dominant portion having its top surface at the level L1. This is because, even if the protrusion is at the M92 portion with the smaller metal-to-metal distance T2 with the adjacent capacitance-dominant metal lines M8 and M10, a via landing region needs to be formed at the same level as the top surfaces of the resistance-dominant portions of the other metal lines such as the M91 portion of the metal line M9 which can also provide a via landing region on their top surfaces.

For example, as the top surface of the protrusion at the M92 portion of the metal line M9 is at the same level L2 as the top surface of the M91 portion of the metal line M9, vias of an upper layer having a same height may be able to contact both the top surface of the protrusion and the top surface of the M91 portion of the metal line M9.

In step S50, the 2^{nd} hard mask patterns may be removed from the metal lines, and a barrier layer may be formed to surround a top surface and a side surface of each of the metal lines, and an IMD layer may be formed to surround the metal lines with the barrier layers thereon.

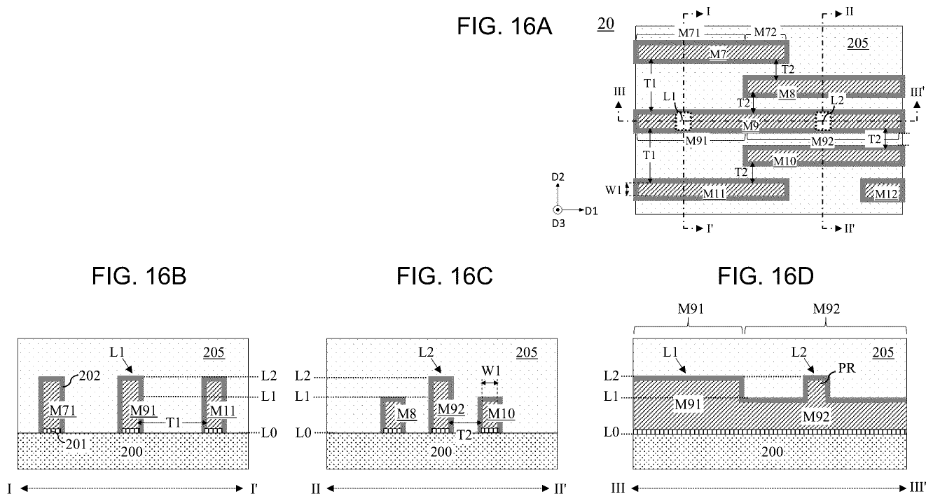

Referring to FIGS. 16A-16D, the 2^{nd} hard mask patterns H13-H16 may be removed from the M71 portion of the metal line M7, the M91 portion of the metal line M9, the part of the M92 portion of the metal line M9 provided for via landing, and the metal line M11 through, for example, stripping or ashing, to expose top surfaces thereof. Then, a barrier layer 202 may be formed on the exposed top surfaces and side surfaces of these metal lines through, for example, atomic layer deposition (ALD) of at least one of nitride (e.g., SiN), Ti, TiN, Ta, TaN, etc.

An IMD layer 205 may be formed to surround the metal lines M7-M12 with the barrier layer 202 thereon by depositing a low-k dielectric material such as silicon oxide (e.g., SiO₂), not being limited thereto through, for example, PVD, CVD, PECVD, ALD, or so on followed by CMP, not being limited thereto.

Through the above-described steps, an interconnect structure 20 shown in FIGS. 2A-2D may be manufactured to include the metal lines M7-M12, in which the resistance-dominant portions have a greater height and the capacitance-dominant portions have smaller height to achieve improved RC characteristics, and further, the metal line M9 provides a via landing region L1 on a top surface of the resistance-dominant portion M91 and a via landing region L2 on a top surface of the protrusion in the capacitance-dominant portion M92 to achieve improved connection performance with respect to other circuit elements such as another interconnect structure.

The above embodiments of the interconnect structure 20 may be applied to various semiconductor cell layouts as below.

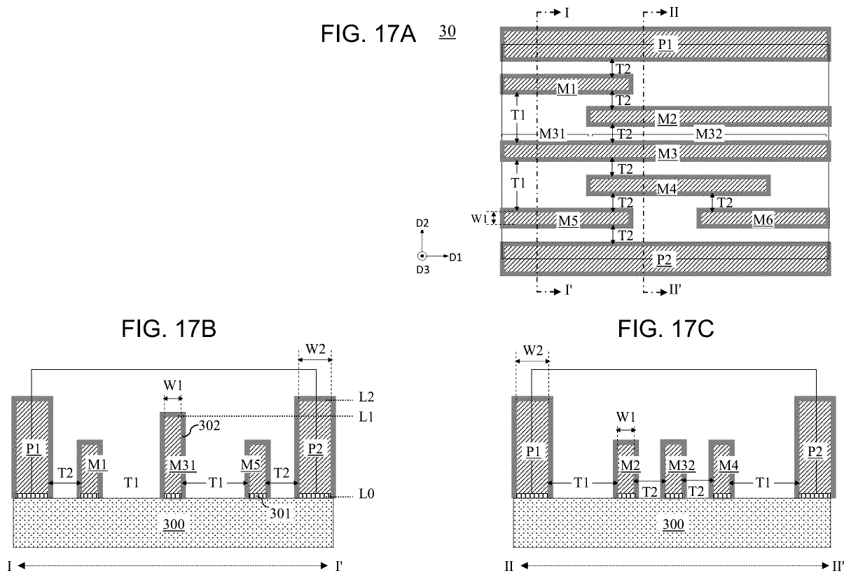

FIGS. 17A-17C illustrate a semiconductor cell in which a plurality of metal lines having different heights are placed, according to one or more embodiments. FIG. 17A is a layout of the semiconductor cell, and FIGS. 17B and 17C are cross-sectional views of the semiconductor cell taken along lines I-I′ and II-II′ shown in FIG. 1A, respectively.

Referring to FIGS. 17A-17C, a semiconductor cell 30 may include an interconnect structure in which a plurality of metal lines M1-M7 and power rails P1 and P2 are extended in the D1 direction and arranged in the D2 direction with corresponding metal-to-metal distances therebetween. The power rails P1 and P2 may be formed on two opposite boundaries of the semiconductor cell 30. The metal lines M1-M7 and the power rails P1 and P2 may be formed above a base layer 300 with an adhesion layer 301 therebetween. The base layer 300 may be another interconnect structure in a BEOL layer or a structure of an MOL layer or an FEOL layer. The base layer 300 may also be referred to as a transistor structure including an FEOL structure, an MOL structure and/or a BEOL structure. Thus, the interconnect structure in the semiconductor cell 30 along with the base layer 300 may form a semiconductor device such as a microprocessor or a memory device.

Each of the metal lines M1-M7 may have a width W1 in the D2 direction, and each of the power rails P1 and P2 may have a width W2 greater than the width W1 in the D2 direction. The metal lines M1-M7 and the power rails P1 and P2 may be formed of ruthenium (Ru) or molybdenum (Mo) and surrounded by a barrier layer 302 formed of at least one of silicon nitride (e.g., SiN), Ti, TiN, Ta, TaN, etc. The adhesion layer 301 may be formed of at last one of Ti, TiN, Ta, TaN, etc.

It is to be understood here that the metal lines M1-M6 of the semiconductor cell 20 shown in FIGS. 17A-17C are not the same as the metal lines M1-M6 of the interconnect structure 10 or the metal lines M7-M12 of the interconnect structure 20 shown in FIGS. 1A-1D to FIGS. 16A-16D. However, similar to the metal lines M1-M12 in the interconnect structures 10 and 20, the metal lines M1-M6 in the semiconductor cell 30 may also be formed to have different heights in a same layer based on metal-to-metal distances or whether they are resistance-dominant or capacitance-dominant.

For example, an M31 portion of the metal line M3 may be resistance-dominant, and an M32 portion of the metal line M3 may be capacitance-dominant because the M31 portion is distant from each of the adjacent metal lines M1 and M5 by a metal-to-metal distance T1 which is greater than a metal-to-metal distance T2 between the M32 portion and each of the adjacent metal lines M2 and M4, in the D2 direction. Accordingly, the metal lines M2 and M4 may also be capacitance-dominant like the M32 portion of the metal line M3. Further, the metal lines M1, M2 and M6 are distant from the power rails P1 and P2, respectively, by the small metal-to-metal distance T2, in the D2 direction. Thus, these capacitance-dominant metal lines M1, M2, M4, M5, M6 and the M32 portion of the metal line M3 may all have their top surfaces at a level L1 based on a level L0 of a top surface of the base layer 300, while the M31 portion of the metal line M3, which is resistance-dominant, has a top surface at a level L2 higher than the level L1.

In contrast, each of the power rails P1 and P2 is a resistance-dominant metal line connected to either a positive voltage source (VDD) or a negative voltage source (VSS or ground), and thus, the power rails P1 and P2 may be more sensitive to resistance. Accordingly, the power rails P1 and P2 may be formed to have a greater volume than the metal lines M1-M7 regardless of the presence of the adjacent metal lines M1 and M5 distant by the small metal-to-metal distance T2 to cause increase capacitance. At least for this reason, each of the power rails P1 and P2 may have its top surface at the level L2 in addition to its width W2, which is greater than the width W1 of each of the metal lines M1-M6. Thus, a semiconductor device formed based on the semiconductor cell 30 may have improved RC characteristics.

In the above embodiments described in reference to FIGS. 1A-1D to FIGS. 17A-17C, the capacitance-dominant portions of metal lines or the capacitance-dominant metal lines are described as having the same metal-to-metal distance T2 which is smaller than the metal-to-metal distance T1 of the resistance-dominant portion of metal lines or the resistance-dominant metal lines. However, the disclosure is not limited thereto. According to one or more other embodiments, the capacitance-dominant portions of metal lines or the capacitance-dominant metal lines may have different metal-to-metal distances as long as this metal-to-metal distance is smaller than the metal-to-metal distance T1 of the resistance-dominant portion of metal lines or the resistance-dominant metal lines. For example, in FIGS. 1A-1D, the M12 portion of the metal line M1, the metal line M2, the M32 portion of the metal line M3, the metal line M4, and the metal line M5 have the same metal-to-metal distance T2. However, these metal lines may have different metal-to-metal distances which are smaller than the metal-to-metal distance T1 to be determined as capacitance-dominant metal lines.

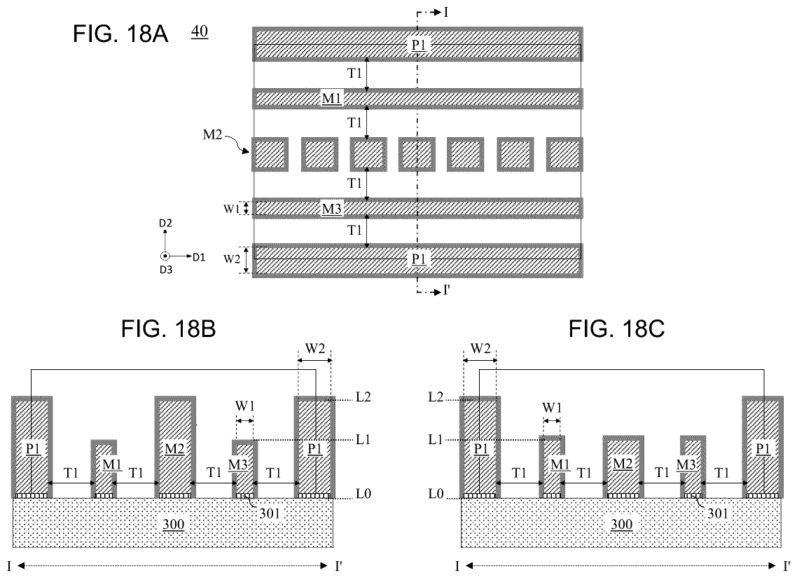

FIGS. 18A-18C illustrate a semiconductor cell for a static random-access memory (SRAM) in which a plurality of metal lines having different heights are placed, according to one or more embodiments. FIG. 18A is a layout of the semiconductor cell, and FIGS. 18B and 18C are cross-sectional views of the semiconductor cell taken along lines I-I′ in FIG. 1A in different cases.

Referring to FIGS. 18A-18C, a semiconductor cell 40 may include a plurality of metal lines M1-M3 and power rails P1 which form an interconnect structure of an SRAM circuit.

The power rails P1 formed on two opposite boundaries of the semiconductor cell 40 may each be connected to a positive voltage source (VDD). The metal lines M1 and M3 extended in the D1 direction may each be a bit line of the SRAM circuit, and the metal lines M2 arranged in the D1 direction may each be a word line or a power rail connected to a negative voltage source (VSS or ground). Further, the power rails P1, the metal lines M1, M2 and M3 may all have a same metal-to-metal distance T1 in the D2 direction.

As described in the above embodiments, power rails may be sensitive to resistance more than other metal lines used for signal routing. Further, in an SRAM circuit, word lines activating specific rows of memory cells are resistance-dominant while the bit lines carrying data from the memory cell are capacitance-dominant. Thus, the power rails P1 and the metal lines M2, each of which is a power rail or a word line may be formed to have a greater volume than the metal lines M1 and M3 which are bit lines, regardless of a metal-to-metal distance with an adjacent metal line. For example, as shown in FIG. 18B, the power rails P1 and the metal line M2 may have their top surfaces at a level L2 which is greater than top surfaces of the metal lines M1 and M3. Further, the power rails P1 and the metal line M2 may have a width W2 which is greater than a width W1 of each of the metal lines M1 and M3.

In the meantime, a power rail connected to a negative voltage source may be less sensitive to resistance than a power rail connected to a positive voltage source. Further, in an SRAM circuit, word lines may also be less sensitive to resistance than the power rail connected to the positive voltage source. Thus, as shown in FIG. 18C, the semiconductor cell 40 may be configured to have small-height metal lines M2 while these metal lines M2 may still have the greater width W2 than the metal lines M1 and M3.

Thus, a semiconductor device formed based on the semiconductor cell 40 may also have improved RC characteristics.

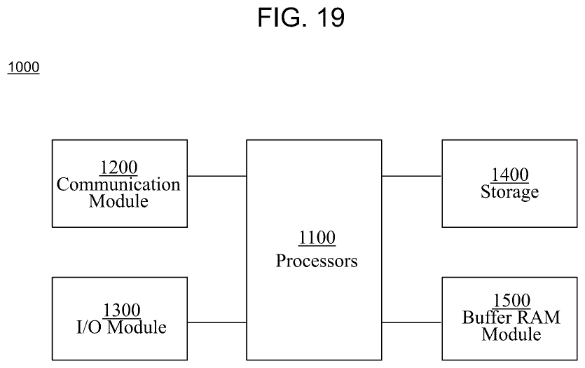

FIG. 19 is a schematic block diagram illustrating an electronic device including at least one of the interconnect structures 10, 20, the interconnect structure based on the semiconductor cell 30, and interconnect structure based on the semiconductor cell 40 as shown in FIGS. 1A-1D to 18A-18C, according to one or more embodiments.

Referring to FIG. 19, an electronic device 1000 may include at least one processor 1100, a communication module 1200, an input/output module 1300, a storage 1400, and a buffer random access memory (RAM) module 1500. The electronic device 1000 may be a mobile device such as a smartphone or a tablet computer, not being limited thereto, according to embodiments.

The processor 1100 may include a central processing unit (CPU), a graphic processing unit (GPU) and/or any other processors that control operations of the electronic device 1000. The communication module 1200 may be implemented to perform wireless or wire communications with an external device. The input/output module 1300 may include at least one of a touch sensor, a touch panel a key board, a mouse, a proximate sensor, a microphone, etc. to receive an input, and at least one of a display, a speaker, etc. to generate an output signal processed by the processor 1100. The storage 1400 may be implemented to store user data input through the input/output module 1300, the output signal, etc. The storage 1400 may be an embedded multimedia card (eMMC), a solid state drive (SSD), a universal flash storage (UFS) device, etc.

The buffer RAM module 1500 may temporarily store data used for processing operations of the electronic device 1000. For example, the buffer RAM 1500 may include a volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

Although not shown in FIG. 19, the electronic device 1000 may further include at least one sensor such as an image sensor.

At least one component in the electronic device 1000 may include at least one of the interconnect structures 10, 20, the interconnect structure based on the semiconductor cell 30, and interconnect structure based on the semiconductor cell 40 as shown in FIGS. 1A-1D to 18A-18C, according to one or more embodiments.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

1. A semiconductor device comprising:
a base layer comprising at least one transistor structure; and
an interconnect structure above the base layer in a 3^{rd} direction,
wherein the interconnect structure comprises a 1^{st} metal line, a 2^{nd} metal line, and at least one another metal line extended in a 1^{st} direction and arranged at a 2^{nd} direction,
wherein at least a 1^{st} portion of the 1^{st} metal line having a 1^{st} metal-to-metal distance to at least a portion of another metal line adjacent thereto in the 2^{nd} direction has a greater height than at least a 1^{st} portion of the 2^{nd} metal line having a 2^{nd} metal-to-metal distance to at least a portion of another metal line adjacent thereto in the 2^{nd} direction,
wherein the 1^{st} metal-to-metal distance is greater than the 2^{nd} metal-to-metal distance, and
wherein the 1^{st} direction and the 2^{nd} direction horizontally intersect each other, and vertically intersect the 3^{rd} direction.

2. The semiconductor device of claim 1, wherein the 1^{st} metal line and the 2^{nd} metal line have a same width in the 2^{nd} direction.

3. The semiconductor device of claim 1, wherein the interconnect structure further comprise a 3^{rd} metal line having a 3^{rd} metal-to-metal distance to at least a portion of another metal line adjacent thereto has a greater height than the 1^{st} metal line,
wherein the 3^{rd} metal-to-metal distance is the same as the 1^{st} metal-to-metal distance or smaller than the 2^{nd} metal-to-metal distance.

4. The semiconductor device claim 2, wherein the 3^{rd} metal line is a power rail connected to a voltage source.

5. The semiconductor device of claim 1, wherein the 1^{st} metal line comprises a 2^{nd} portion having a smaller height than the 1^{st} a portion.

6. The semiconductor device of claim 5, wherein the 2^{nd} portion of the 1^{st} metal line has a 3^{rd} metal-to-metal distance to at least a portion of another metal line adjacent thereto, and
wherein the 3^{rd} metal-to-metal distance is smaller than the 1^{st} metal-to-metal distance.

7. The semiconductor device of claim 1, further comprising a 1^{st} top via on the 1^{st} portion of the 1^{st} metal line,
wherein the 1^{st} top via and the 1^{st} portion does not have a connection surface, boundary or interface therebetween.

8. The semiconductor device of claim 7, wherein the 1^{st} metal line and the 1^{st} top via comprise ruthenium (Ru).

9. The semiconductor device of claim 7, further comprising a 2^{nd} top via on the 2^{nd} portion of the 1^{st} metal line,
wherein the 2^{nd} top via and the 2^{nd} portion does not have a connection surface, boundary or interface therebetween.

10. (canceled)

11. The semiconductor device of claim 9, wherein a top surface of the 1^{st} top via is at a same level as a top surface of the 2^{nd} top via.

12. The semiconductor device of claim 1, wherein a top surface of the 1^{st} portion of the 1^{st} metal line is at a level higher than a top surface of the 1^{st} portion of the 2^{nd} metal line.

13-16. (canceled)

17. A semiconductor device comprising:
a base layer comprising at least one transistor structure; and
an interconnect structure above the base layer in a 3^{rd} direction,
wherein the interconnect structure comprises a plurality of metal lines extended in a 1^{st} direction and arranged at a 2^{nd} direction,
wherein, in the plurality of metal lines, a 1^{st} metal line comprises a 1^{st} portion having a 1^{st} metal-to-metal distance to at least a portion of a 2^{nd} metal line and a 2^{nd} portion having a 2^{nd} metal-to-metal distance to at least a portion of a 3^{rd} metal line,
wherein a top surface of the 1^{st} portion is at a level higher than a top surface of the 2^{nd} portion, and
wherein the 1^{st} direction and the 2^{nd} direction are horizontally intersect each other, and vertically intersect the 3^{rd} direction.

18. The semiconductor device of claim 17, wherein the interconnect structure further comprises a 1^{st} top via formed on the 1^{st} portion of the 1^{st} metal line without a connection surface, boundary or interface therebetween.

19. The semiconductor device of claim 18, wherein the 1^{st} metal line and the 1^{st} top via comprise ruthenium (Ru).

20. The semiconductor device of claim 18, wherein the interconnect structure further comprises a 2^{nd} top via formed on the 2^{nd} portion of the 1^{st} metal line without a connection surface, boundary or interface therebetween.

21. The semiconductor device of claim 20, wherein a top surface of the 1^{st} top via is at a same level as a top surface of the 2^{nd} top via.

22. The semiconductor device of claim 17, wherein the 1^{st} to 3^{rd} metal lines have a same width in the 2^{nd} direction.

23. A semiconductor device comprising:
a base layer comprising at least one transistor structure; and
an interconnect structure above the base layer in a 3^{rd} direction,
wherein the interconnect structure comprises a 1^{st} top via and a 2^{nd} top via formed on a 1^{st} portion and a 2^{nd} portion of a 1^{st} metal line without a connection surface, boundary or interface therebetween,
wherein the 1^{st} top via has a greater height than the 2^{nd} top via, and
wherein a horizontal distance between the 1^{st} top via and at least a portion of another metal line adjacent thereto is greater than a horizontal distance between the 2^{nd} top via and at least a portion of another metal line adjacent thereto.

24. The semiconductor device of claim of claim 23, wherein a top surface of the 1^{st} top via is at a same level as a top surface of the 2^{nd} top via.

25. The semiconductor device of claim 23, wherein the 1^{st} metal line, the 1^{st} top via, and the 2^{nd} top via comprise ruthenium (Ru).

26-42. (canceled)
